(19) United States
(12) Patent Application Publication
(10) Pub. No.: US 2014/0139257 A1
(43) Pub. Date: May 22, 2014

(54) APPARATUS AND METHOD FOR EXTRACTING RESISTANCE AND COMPUTER-READABLE RECORDING MEDIUM

(71) Applicant: KYUNGPOOK NATIONAL UNIVERSITY INDUSTRY ACADEMIC COOPERATION FOUNDATION, Daegu (KR)

(72) Inventor: In-man KANG, Daegu (KR)

(73) Assignee: KYUNGPOOK NATIONAL UNIVERSITY INDUSTRY ACADEMIC COOPERATION FOUNDATION, Daegu (KR)

(21) Appl. No.: 14/085,243

(22) Filed: Nov. 20, 2013

(30) Foreign Application Priority Data
Nov. 21, 2012 (KR) 10-2012-0132558

(51) Int. Cl. G01R 31/26

(52) U.S. Cl. CPC G01R 31/2601
USPC 324/762.01

(57) ABSTRACT

A resistance extracting apparatus, a resistance extracting method, and a computer-readable recording medium are provided. A resistance extracting apparatus includes an interface unit which receives parameter values of a semiconductor device, which are measured in a turn-on state and a turn-off state of the semiconductor device, a resistance value extracting unit which extracts resistance values which are independent from voltage applied to the semiconductor device using the parameter value measured in the turn-off state, and extracts resistance values which are dependent on the voltage using the parameter value measured in the turn-on state, and a control unit which controls the resistance value extracting unit to extract the independent resistance values and the dependent resistance values using the received parameter values.

### CROSS-REFERENCE TO RELATED APPLICATIONS

This application claims priority from Korean Patent Application No. 10-2012-0132558, filed on Nov. 21, 2012, in the Korean Intellectual Property Office, the disclosure of which is incorporated herein by reference in its entirety.

### BACKGROUND OF THE INVENTION

### Field of the Invention

Apparatuses and methods consistent with the present invention relate to an apparatus and method for extracting resistance and a computer-readable recording medium, and more particularly, to a resistance extracting apparatus which separates and extracts components which are dependent on or independent from bias applied to a semiconductor device in order to extract source and drain resistance of a transistor such as a silicon nanowire metal-oxide semiconductor field effect transistor (MOSFET), a method for extracting resistance, and a computer-readable recording medium.

### Description of the Related Art

Until now, development and study of a next generation device structure has been proceeded to be used for construction of diverse memories, central processing units (CPUs) and digital circuits which are applied to a computer system. Ultimately, development and study of a next generation device structure is aimed at implementing a high-integrated and low-power system on chip (SoC) by refinement of a complementary metal-oxide semiconductor (CMOS) device.

However, a recent multifunctional integrated circuit which is widely used in satellite communication, automobile system, an mobile wireless communication market does not consist of a digital block, but includes transmission/reception blocks of radio frequency (RF)/analog signals and diverse RF/analog blocks such as a transceiver, an RF low-noise amplifier (LNA), and a mixer.

Accordingly, in order to design a precise high-frequency block circuit, a precise super high frequency model for a unit device and a method for extracting a parameter should be developed as well as development of the CMOS device, and verification of the circuit is needed.

In the related art, a method for extracting resistance based on a high frequency was known. However, such a method requires linear regression analysis and thus may cause errors due to the change in values measured during the analysis. Accordingly, it is difficult to secure precise and reliable data.

### SUMMARY OF THE INVENTION

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a resistance extracting apparatus which separates and extracts components which are dependent on or independent from bias applied to a semiconductor device in order to extract source and drain resistance of a transistor such as a silicon nanowire metal-oxide semiconductor field effect transistor (MOSFET), a method for extracting resistance, and a computer-readable recording medium.

According to an aspect of the present invention, a resistance extracting apparatus includes an interface unit which receives parameter values of a semiconductor device, which are measured in a turn-on state and a turn-off state of the semiconductor device, a resistance value extracting unit which extracts resistance values which are independent from voltage applied to the semiconductor device using the parameter value measured in the turn-off state, and extracts resistance values which are dependent on the voltage using the parameter value measured in the turn-on state, and a control unit which controls the resistance value extracting unit to extract the independent resistance values and the dependent resistance values using the received parameter values.

The resistance value extracting unit may use Y-parameter values of the semiconductor device to extract the independent resistance values, and use Z-parameter values of the semiconductor device to extract the dependent resistance values.

The resistance value extracting unit may extract the independent resistance values in the turn-off state, de-embed the extracted independent resistance values from the parameter value of the turn-on state, and extract the dependent resistance values using the Z-parameter value after the de-embedding.

The resistance value extracting unit may extract each resistance value according to change in a frequency.

The semiconductor device may include heavily doped drain (HDD) areas and lightly doped drain (LDD) areas which are formed in a channel layer between a source electrode and a drain electrode, the HDD areas may be formed adjacent to the source electrode and the drain electrode respectively, and the LDD areas may be formed adjacent to the HDD areas respectively.

The HDD areas may include the independent resistance values and the LDD areas may include the dependent resistance values.

According to another aspect of the present invention, a resistance extracting method includes receiving a parameter value measured in a turn-off state of a semiconductor device, extracting resistance values which are independent from voltage applied to the semiconductor device using the parameter value measured in the turn-off state, receiving a parameter value measured in a turn-on state of the semiconductor device, and extracting resistance values which are dependent on the voltage applied to the semiconductor device using the parameter value measured in the turn-on state.

In the extracting of the dependent resistance values, Z-parameter values may be used, and in the extracting of the independent resistance values, Y-parameter values may be used.

In the extracting of the dependent resistance values, the dependent resistance values may be extracted by de-embedding the independent resistance values which are measured and extracted in the turn-off state, from the Z-parameter values measured in the turn-on state.

The semiconductor device may include heavily doped drain (HDD) areas and lightly doped drain (LDD) areas which are formed in a channel layer between a source electrode and a drain electrode, the HDD areas may be formed adjacent to the source electrode and the drain electrode respectively, and the LDD areas may be formed adjacent to the HDD areas respectively.

In the extracting of the independent resistance values, resistance values of the HDD areas may be extracted, and in the extracting of the dependent resistance values, resistance values of the LDD areas may be extracted.

According to yet another aspect of the present invention, a computer-readable recording medium including a program to execute a resistance extracting method including receiving a parameter value measured in a turn-off state of a semiconductor device, extracting resistance values which are independent from voltage applied to the semiconductor device using the parameter value measured in the turn-off state, receiving a parameter value measured in a turn-on state of the semiconductor device, and extracting resistance values which are dependent on the voltage applied to the semiconductor device using the parameter value measured in the turn-on state.

Additional and/or other aspects and advantages of the invention will be set forth in part in the description which follows and, in part, will be obvious from the description, or may be learned by practice of the invention.

### BRIEF DESCRIPTION OF THE DRAWING FIGURES

The above and/or other aspects of the present invention will be more apparent by describing certain exemplary embodiments of the present invention with reference to the accompanying drawings, in which:

FIG. 1 illustrates a semiconductor device verification system according to an exemplary embodiment of the present invention;

FIG. 2 is a cross-sectional view illustrating a semiconductor device cut along a cutting-plane line, I-I′, shown in FIG. 1;

FIG. 3 is a block diagram illustrating a detailed structure of the resistance extracting apparatus shown in FIG. 1;

FIG. 4 is an equivalent circuit diagram showing when voltage is applied to the semiconductor device shown in FIG. 1;

FIG. 5 is an equivalent circuit diagram showing when voltage is not applied to the semiconductor device shown in FIG. 1;

FIGS. 6 to 9 illustrate simulation results according to an exemplary embodiment of the present invention;

FIG. 10 illustrates a process of verifying a semiconductor device according to an exemplary embodiment of the present invention; and

FIG. 11 is a flow chart illustrating a method for extracting resistances according to an exemplary embodiment of the present invention.

### DETAILED DESCRIPTION OF THE EXEMPLARY EMBODIMENTS

Certain exemplary embodiments of the present invention will now be described in greater detail with reference to the accompanying drawings.

In the following description, same drawing reference numerals are used for the same elements even in different drawings. The matters defined in the description, such as detailed construction and elements, are provided to assist in a comprehensive understanding of the invention. Thus, it is apparent that the exemplary embodiments of the present invention can be carried out without those specifically defined matters. Also, well-known functions or constructions are not described in detail since they would obscure the invention with unnecessary detail.

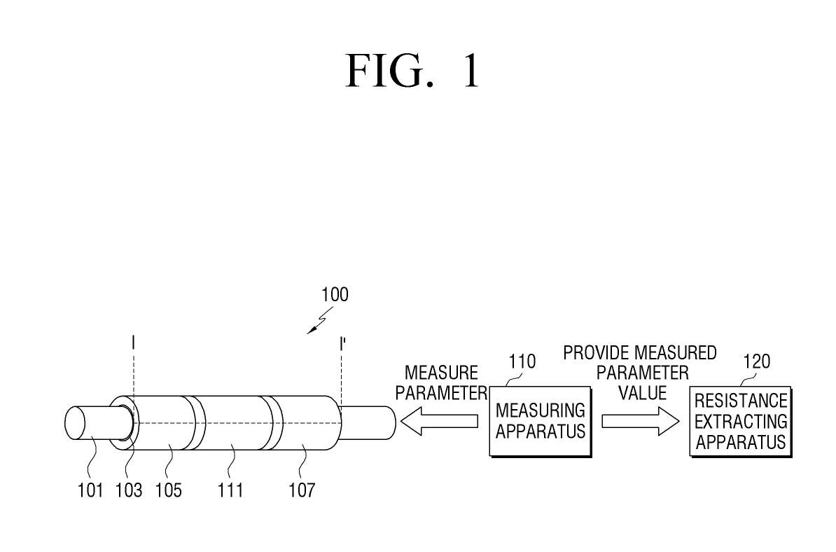

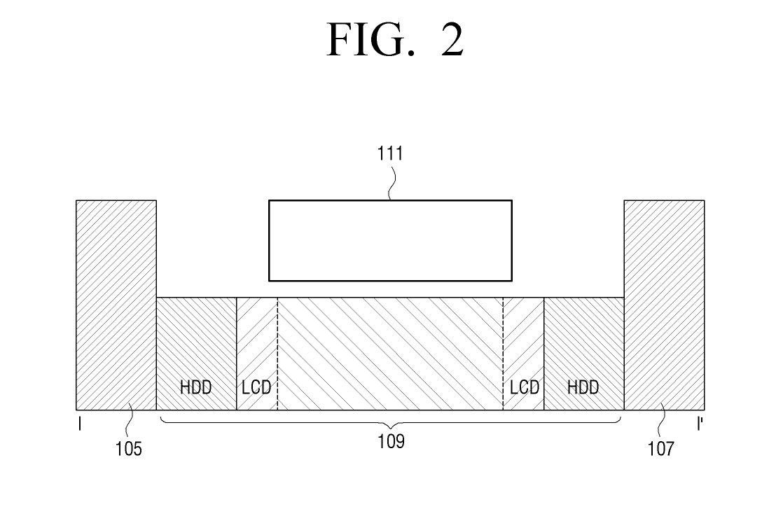

FIG. 1 illustrates a semiconductor device verification system according to an exemplary embodiment of the present invention, and FIG. 2 is a cross-sectional view illustrating a semiconductor device cut along a cutting-plane line, I-I′, shown in FIG. 1.

As shown in FIGS. 1 and 2, the semiconductor device verification system 1000 according to an exemplary embodiment of the present invention may include part or all of a measuring apparatus 110 and a resistance extracting apparatus 120, and may further include a semiconductor device 100.

Herein, including part or all of them indicates omitting some component or integrating some component such as the resistance extracting apparatus 120 into another component such as the measuring apparatus 110. For sufficient understanding of the present invention, description is given including all of them.

The semiconductor device 100 according to an exemplary embodiment of the present invention may be a silicon nanowire metal-oxide semiconductor field effect transistor (MOSFET), but may also include all types of MOSFET devices. More precisely, devices such as a nanowire and a SOI FinFET in which a source, a channel, and a drain separate from a substrate unlike general MOSFETs, or devices having low substrate resistance and junction capacitance from among general MOSFETs may be suitable for the semiconductor device 100.

For example, a silicon nanowire MOSFET may include a gate oxide film 103 which surrounds a silicon nanowire 101, a source electrode 105, a drain electrode 107, a channel layer 109, and a gate electrode 111 as shown in FIGS. 1 and 2. The source and drain electrodes 105 and 107 and the gate electrode 111 are cylindrically formed. The channel layer 109 may include heavily doped drain (HDD) areas and lightly doped drain (LDD) areas so as to have a short length to prevent short channel effect. The LDD areas have lower dopant concentration and lower depth than the HDD areas, but are closer to the gate electrode 111 and determine a channel length of the MOSFET. On the contrary, the HDD areas have lower contact resistance.

The measuring apparatus 110 may include a phase network analyzer (PNA) which measures a radio frequency (RF). The measuring apparatus 110 measures parameters when bias voltage is applied to the semiconductor device 100 or is not applied. The parameters may include Y-parameters and Z-parameters of the semiconductor device 100. For example, the measuring apparatus 110 may measure input and output admittances Y₁₁ and Y₂₂ and forward and backward transfer admittances Y₁₂ and Y₂₁ in order to measure the Y-parameters.

More specifically, the measuring apparatus 110 may measure Z-parameters when the semiconductor device 100 operates in strong inversion (V_{GS}>Vth, V_{DS}=0V), and the measuring apparatus 110 may measure Y-parameters when the semiconductor device 100 is in the turn-off state (i.e. V_{GS}=V_{DS}=0V). Subsequently, the measuring apparatus 110 provides the measuring results to the resistance extracting apparatus 120.

In addition, the measuring apparatus 110 may adjust a frequency. In an exemplary embodiment of the present invention, a frequency may be adjusted in a range of approximately 100 GHz. For example, the measuring apparatus 110 is connected to the resistance extracting apparatus 120 to adjust a frequency. The measuring apparatus 110 may verify how a resistance value of the semiconductor device 100 extracted by the resistance extracting apparatus 120, i.e. a capacitance value, changes according to the change in the adjusted frequency. As a result, if the change according to the frequency is regular, a method for extracting resistance according to an exemplary embodiment of the present invention is reliable.

After reliability is verified, if a resistance value and a capacitance value of the semiconductor device 100 are not regular with regard to the change of the frequency, it may be a basis for determining that the semiconductor device 100 is defective. As a result, when designing a circuit, an appropriate correction circuit may be added using such a basis.

The resistance extracting apparatus 120 may be a desktop computer or a terminal device such as a notebook computer, a smart phone and the like. The resistance extracting apparatus 120 receives and analyzes parameter values measured by the measuring apparatus 110. Based on the analysis, the resistance extracting apparatus 120 may extract resistance values which are independent from and dependent on bias voltage of the semiconductor device 100. For example, the resistance extracting apparatus 120 may extract resistance values by storing a program of an algorithm format in which channel resistance in the turn-off state of the semiconductor device 100 is reflected and executing the program.

For example, the resistance extracting apparatus 120 may extract resistance components which are independent from bias voltage V_{GS} using Y-parameter values measured when the semiconductor device 100 is in the turn-off state. In addition, the resistance extracting apparatus 120 may extract resistance components which are dependent on bias voltage V_{GS} using Z-parameter values measured when the semiconductor device 100 is in the turn-on state. The dependent resistance component values are extracted by extracting the independent resistance component values in the turn-off state, de-embedding the extracted independent resistance component values from parameter values in the turn-on state, and using Z-parameter values. More detailed description will be given below.

In addition, the resistance extracting apparatus 120 may show simulation results with regard to how the extracted resistance values, i.e. capacitance values change according to change in the frequency adjusted by the measuring apparatus 110. The simulation results may be used for reliability verification of the resistance extracting method proposed in the exemplary embodiment of the present invention.

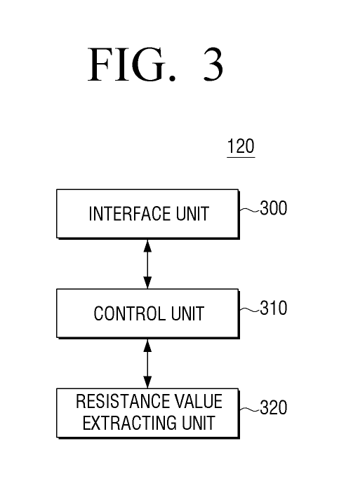

FIG. 3 is a block diagram illustrating a detailed structure of the resistance extracting apparatus of FIG. 1.

With reference to FIGS. 1 and 3, the resistance extracting apparatus 120 according to an exemplary embodiment of the present invention may include part or all of an interface unit 300, a control unit 310, and a resistance value extracting unit 320, and further include a storage unit. Herein, including part or all of them is the same as described above.

The interface unit 300 may include a communication interface unit and a user interface unit. The user interface unit may include a button unit or a display unit to input a user command. The interface unit 300, or more specifically, the communication interface unit, receives parameter values of the semiconductor device 100 measured by the measuring apparatus 110. The parameter values are parameters (i.e. the Y-parameters and Z-parameters) measured when the semiconductor device 100 is in the turn-on state and turn-off state.

The control unit 310 controls the overall operation of the interface unit 300 and the resistance value extracting unit 320. For example, the control unit 310 may provide the resistance value extracting unit 320 with a parameter value received to the interface unit 300, and at this moment execute an algorithm or program stored in the resistance value extracting unit 320.

The resistance value extracting unit 320 may analyze the received parameter and extract resistance values included in the parameter, for example, by executing the stored algorithm. The algorithm may be an algorithm in which channel resistance in the turn-off state of the semiconductor device 100 is reflected. The resistance value extracting unit 320 may extract diverse parameter values included in each parameter after receiving the parameter as a result of reflecting diverse resistance parameters. To do so, the resistance value extracting unit 320 may extract resistance components which are independent from bias of the semiconductor device 100 using the Y-parameters which are measured in the turn-off state and are received. In addition, the resistance value extracting unit 320 may extract resistance components which are dependent on bias of the semiconductor device 100 using the Z-parameters which are measured in the turn-on state and are received. At this time, capacitance values may be obtained from an imaginary part of the Y-parameters.

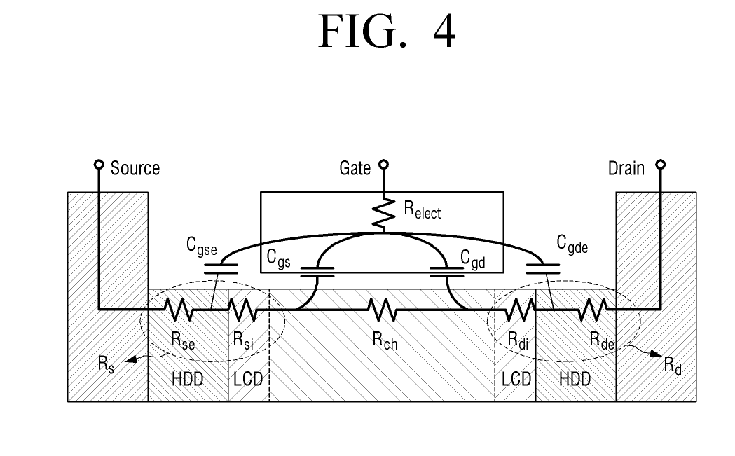

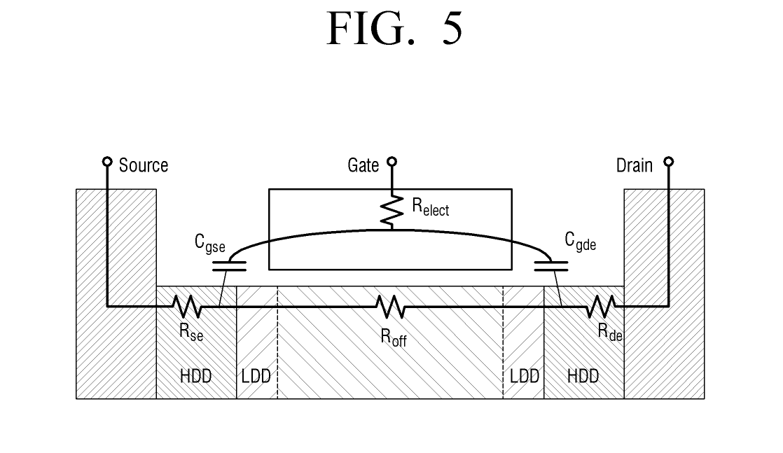

FIG. 4 is an equivalent circuit diagram showing when voltage is applied to the semiconductor device shown in FIG. 1, and FIG. 5 is an equivalent circuit diagram showing when voltage is not applied to the semiconductor device shown in FIG. 1.

FIG. 4 illustrates an equivalent circuit of a silicon nanowire MOSFET in strong inversion, i.e. which operates when bias voltage is applied. In the equivalent circuit, C_{gs} and C_{gd} denote internal gate-source capacitance and internal gate-drain capacitance, and G_{gse} and C_{gde} denote external gate-source capacitance and external gate-drain capacitance. In addition, resistance components, R_{elect} and R_{ch}, denote gate electrode resistance and channel resistance. In terms of source and drain resistances, Rₛᵢ and R_{di} are source and drain series resistances which are dependent on V_{GS}, and Rse and Rde are source and drain series resistances which are independent from V_{GS}.

In addition, when the semiconductor device 100 is turned off, there is no electric charge in the channel. Thus, internal gate capacitance components may be ignored as shown in FIG. 5. In FIG. 5, R_{off} denotes a strong resistance component between the source and drain areas in the turn-off state. The strong resistance by the channel area indicates that there is no inversion layer. The strong resistance is added to the entire series resistance of the MOSFET.

The resistance components, Rₛₑ and R_{de}, which are independent from V_{GS} of the silicon nanowire MOSFET may be extracted by analysis of the Y-parameters in the small-signal circuit of FIG. 4. The Y-parameters in the equivalent circuit simplified when the semiconductor device 100 is turned off may be represented as in [Mathematical Formula 1] to [Mathematical Formula 3].

$$\begin{matrix}{Y}_{11} \approx {ω}^{2} ⌊ \begin{matrix}\begin{matrix}{{R}_{elect} ( {C}_{gse} + {C}_{gde} )}^{2} + \\ {R}_{se} {C}_{gse}^{2} +\end{matrix} \\ {R}_{de} {C}_{gde}^{2}\end{matrix} ⌋ + j ω ( {C}_{gse} + {C}_{gde} ) & [ Mathematical Formula 1 ] \\ {Y}_{12} \approx - {ω}^{2} ⌊ {R}_{elect} {C}_{gde} ( {C}_{gse} + {C}_{gde} ) + {R}_{de} {C}_{gde}^{2} ⌋ - j ω {C}_{gde} & [ Mathematical Formula 2 ] \\ {Y}_{22} \approx \frac{1}{{R}_{off} + {R}_{se} + {R}_{de}} + {ω}^{2} ( {R}_{elect} + {R}_{de} ) {C}_{gde}^{2} + j ω {C}_{gde} & [ Mathematical Formula 3 ]\end{matrix}$$

In [Mathematical Formula 1] to [Mathematical Formula 3], the capacitance may be obtained from an imaginary part of the Y-parameters. Accordingly, mathematical formulas regarding components related to the resistance may be represented as in [Mathematical Formula 4] to [Mathematical Formula 8].

$$\begin{matrix} {R}_{off} + {R}_{se} + {R}_{de} = {( Re ( {Y}_{22} ) {\vert}_{{ω}^{2} = 0} )}^{- 1} & [ Mathematical Formula 4 ] \\ {R}_{de} = \frac{\begin{matrix}{C}_{gde} Re ( {Y}_{12} ) + ( {C}_{gse} + {C}_{gde} ) \\ ( Re ( {Y}_{22} ) - {( {R}_{off} + {R}_{se} + {R}_{de} )}^{- 1} )\end{matrix}}{{ω}^{2} {C}_{gse} {C}_{gde}^{2}} & [ Mathematical Formula 5 ] \\ {R}_{elect} = - \frac{Re ( {Y}_{12} ) + {ω}^{2} {R}_{de} {C}_{gde}^{2}}{{ω}^{2} {C}_{gse} ( {C}_{gse} + {C}_{gde} )} & [ Mathematical Formula 6 ] \\ {R}_{se} = \frac{\begin{matrix}Re ( {Y}_{11} ) - {ω}^{2} {{R}_{elect} ( {C}_{gse} + {C}_{gde} )}^{2} - \\ {ω}^{2} {R}_{de} {C}_{gde}^{2}\end{matrix}}{{ω}^{2} {C}_{gse}^{2}} & [ Mathematical Formula 7 ] \\ {R}_{off} = {( Re ( {Y}_{22} ) {\vert}_{{ω}^{2} = 0} )}^{- 1} - ( {R}_{se} + {R}_{de} ) & [ Mathematical Formula 8 ]\end{matrix}$$

Based on [Mathematical Formula 4] to [Mathematical Formula 8], parameters may be extracted using low frequency data without an asymptotic value at a high frequency.

R_{elect}, Rₛₑ, R_{de}, C_{gse} and C_{gde} are de-embedded from the small-signal equivalent circuit shown FIG. 4. De-embedding is a kind of an inverse matrix using method. In other words, if the resistance values in the turn-off state are extracted first and then are de-embedded (or removed) in the turn-on state, R_{elect}, Rₛₑ, R_{de}, C_{gse} and C_{gde} are removed and the dependent values in the turn-on state may be extracted using Z-parameters.

After de-embedding, Z-parameters may be represented as in [Mathematical Formula 9] to [Mathematical Formula 11].

$$\begin{matrix}Re ( {Z}_{11} ) ≅ {R}_{si} + {{R}_{ch} ( \frac{{C}_{gd}}{{C}_{gs} + {C}_{gd}} )}^{2} & [ Mathematical Formula 9 ] \\ Re ( {Z}_{12} ) ≅ {R}_{si} + {R}_{ch} \frac{{C}_{gd}}{{C}_{gs} + {C}_{gd}} & [ Mathematical Formula 10 ] \\ Re ( {Z}_{22} ) ≅ {R}_{ch} + {R}_{si} + {R}_{di} & [ Mathematical Formula 11 ]\end{matrix}$$

From [Mathematical Formula 9] to [Mathematical Formula 11], Rₛᵢ, R_{di} and R_{ch} may be represented as in [Mathematical Formula 12] to [Mathematical Formula 14].

$$\begin{matrix}{R}_{si} = \frac{{C}_{gs} + {C}_{gd}}{{C}_{gs}} Re ( {Z}_{11} ) - \frac{{C}_{gd}}{{C}_{gs}} Re ( {Z}_{13} ) & [ Mathematical Formula 12 ] \\ {R}_{ch} = \frac{{C}_{gs} + {C}_{gd}}{{C}_{gs}} ( Re ( {Z}_{12} ) - {R}_{si} ) & [ Mathematical Formula 13 ] \\ {R}_{di} = Re ( {Z}_{22} ) - {R}_{ch} - {R}_{si} & [ Mathematical Formula 14 ]\end{matrix}$$

In order to simplify the Y-parameter and Z-parameter formulas in the low frequency above, it is assumed that ω²C²_{gde}(R_{de}+R_{elect}(R_{off}+Rₛₑ)/(R_{off}+Rₛₑ+R_{de}))², ω²R²_{de}C²_{gdc}<<1, ω²R²ₛₑC²_{gse}<<1, ω²R²_{elect}(C_{gse}+C_{gde})²<<1 , ω²R_{elect}(RₛₑC²_{gse}+R_{de}C²_{gde})<<1, and ω²R²_{ch}(C_{gs}C_{gd}/(C_{gs}+C_{gd})₂<<1.

In view of the above, the resistance extracting apparatus 120 as shown in FIG. 1 according to the exemplary embodiment of the present invention calculates resistance values which are independent from and dependent on the bias voltage of the semiconductor device 100 using the Y-parameters and Z-parameters. This extracting process may be performed by implementing an algorithm stored in a recording medium, but it is not limited thereto in the exemplary embodiment of the present invention.

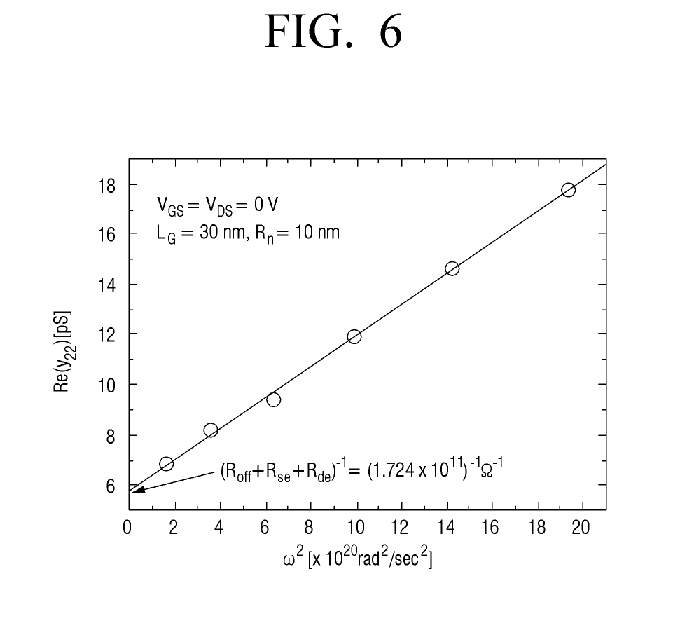

FIGS. 6 to 9 illustrate simulation results to verify a source and drain resistance extracting method according to an exemplary embodiment of the present invention.

As shown in FIGS. 6 to 9 together with FIG. 1 for convenient description, Y-parameters and Z-parameters of the silicon nanowire MOSFET are shown up to a bandwidth of 100 GHz through three-dimensional simulation so as to extract a small-signal parameter using the resistance extracting apparatus 120. The device used for the simulation is 30 nm in channel length and 10 nm in channel radius.

FIG. 6 shows that in the case of V_{GS}=V_{DS}=0V, the y-intercept on the graph is R_{off}+Rₛₑ+R_{de} as a small-signal parameter according to a frequency.

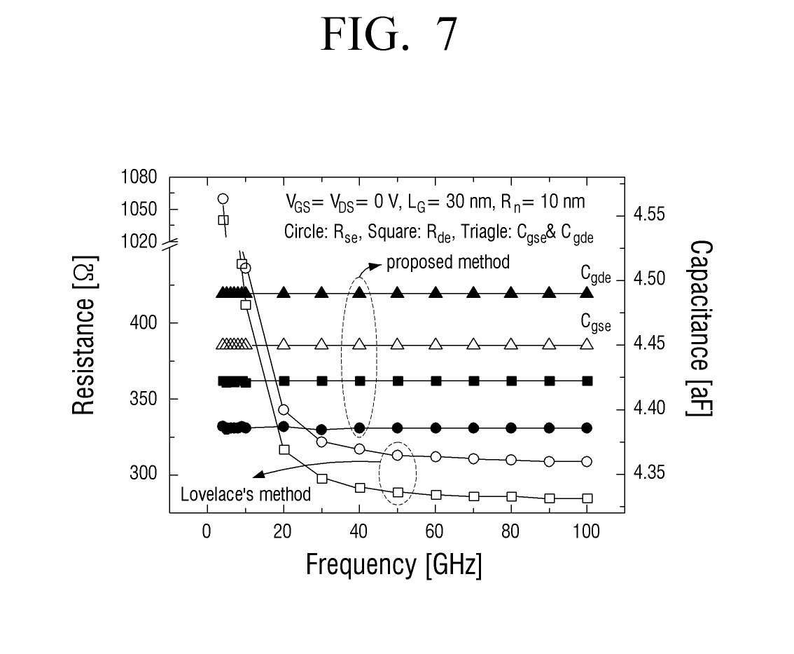

As shown in FIG. 7, the resistances and capacitances extracted by [Mathematical Formula 1] to [Mathematical Formula 8] in the case of V_{GS}=V_{DS}=0V are maintained almost regularly according to a frequency. Based on this result, reliability of the source and drain extracting method proposed to extracted parameters in the exemplary embodiment of the present invention is verified.

On the contrary, as shown in FIG. 7, the resistance components extracted in the Lovelace's method decrease gradually as the frequency increases. Accordingly, it is difficult to extract precise resistance values.

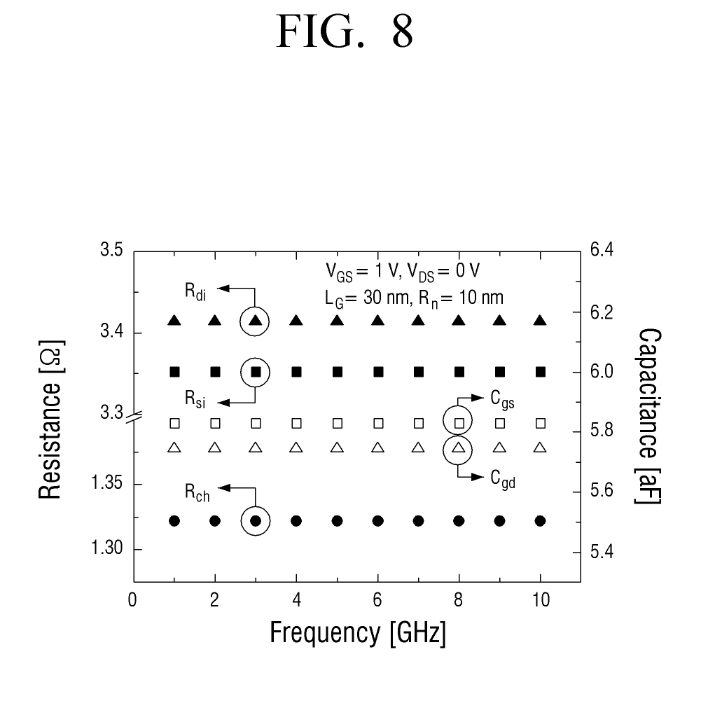

FIG. 8 shows resistance and capacitance which are dependent on the bias in the case of V_{GS}>Vₜₕ. In FIG. 8, the parameters extracted in the low frequency bandwidth are maintained regularly according to a frequency without linear regression.

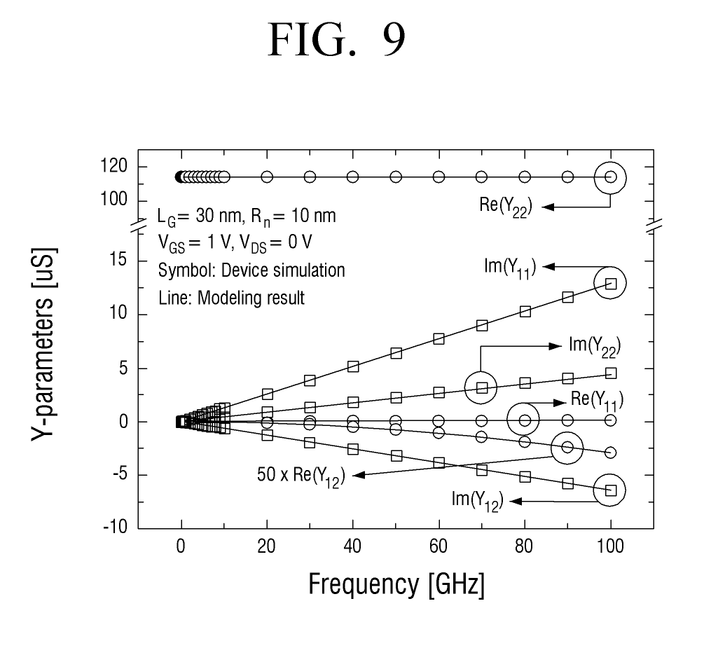

FIG. 9 shows comparison of Y-parameters obtained as a result of the three-dimensional simulation with the above extracted parameter values and the values obtained through HSPICE which is circuit simulation based on the small-signal equivalent circuit model proposed in FIG. 4 so as to verify precision of the extracting method proposed in the exemplary embodiment of the present invention.

As a result, the equivalent circuit simulation result based on the extracting method proposed in the exemplary embodiment of the present invention coincides with the three-dimensional simulation result up to 100 GHz. Based on this result, precision and reliability of the extracting method proposed in the exemplary embodiment of the present invention can be secured.

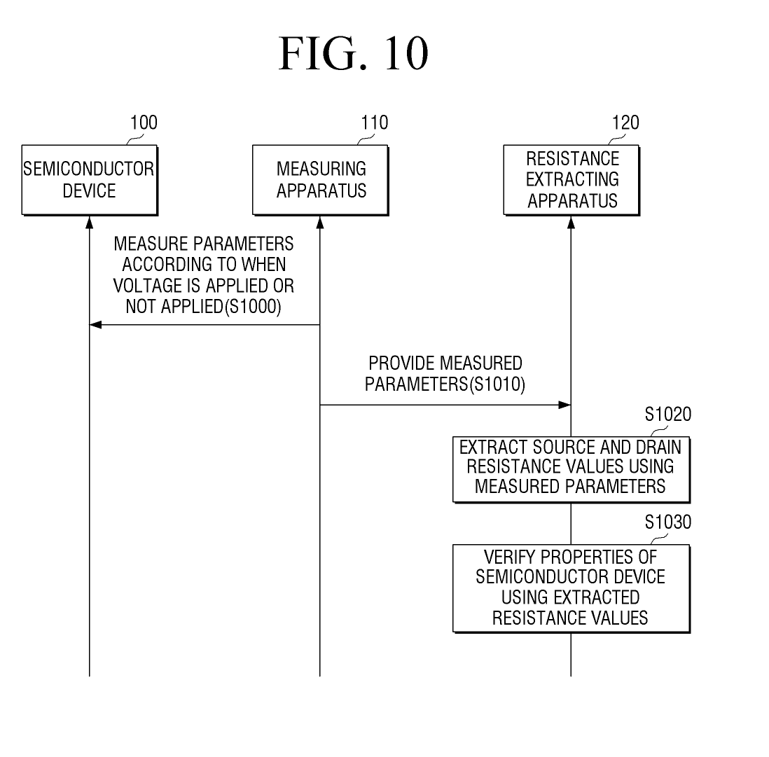

FIG. 10 illustrates a process of verifying a semiconductor device according to an exemplary embodiment of the present invention.

With reference to FIG. 10, in operation S1000, measuring terminals of the measuring apparatus 110 according to an exemplary embodiment of the present invention are connected to both terminals of the semiconductor device 100, i.e. the source electrode 105 and the drain electrode 107 so that Y-parameters and Z-parameters of the semiconductor device 100 can be obtained. The Y-parameters and Z-parameters may include parameters measured when the voltage is applied and not applied. At this time, the parameters may include diverse parameters such as resistance and capacitance components as in [Mathematical Formula 1] to [Mathematical Formula 3] and [Mathematical Formula 9] to [Mathematical Formula 11].

Subsequently, in operation S1010, the measuring apparatus 110 provides the resistance extracting apparatus 120 such as a personal computer (PC) with the measured parameters, i.e. the measured data.

In operation S1020, using the measured data, the resistance extracting apparatus 120 extracts source and drain resistance values of the semiconductor device 100 by implementing an algorithm in which a channel resistance in the turn-on state of the semiconductor device 100 is reflected. For example, the corresponding resistance values are extracted by having the equivalent circuit models as shown in FIGS. 4 and 5.

In operation S1030, the resistance extracting apparatus 120 verifies properties of the semiconductor device 100 by checking what properties the extracted resistance values have according to change in the frequency.

As a result, reliability of the resistance extracting method proposed in the exemplary embodiment of the present invention may be verified and it may be used as a basis to determine whether the semiconductor device 100 is good or defective. If it is determined that the semiconductor device 100 is defective, diverse block circuits can be designed by constituting a circuit to compensate the defective property.

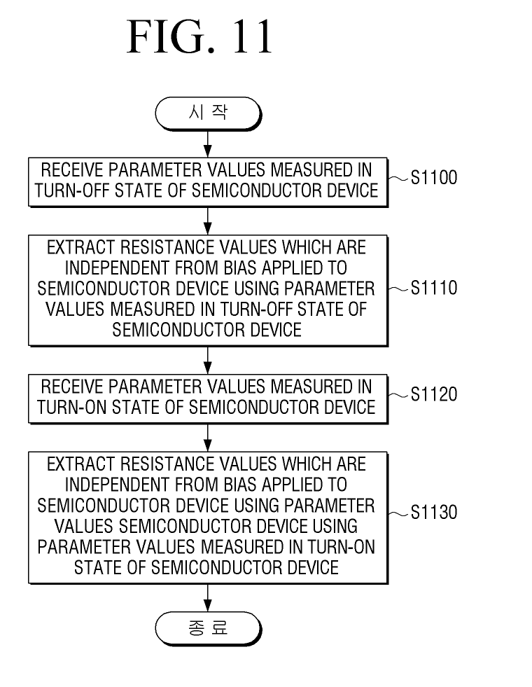

FIG. 11 is a flow chart illustrating a method for extracting resistances according to an exemplary embodiment of the present invention.

With reference to FIG. 11 together with FIGS. 1, 4 and 5, the resistance extracting apparatus 120 receives parameter values measured in the turn-off state of the semiconductor device 100 in operation S1100. The parameters may be Y-parameters of the semiconductor device 100. The parameters may include parameters for input and output admittances and forward and backward transfer admittances in a multi-terminal network.

In operation S1110, the resistance extracting apparatus 120 extracts resistance values which are independent from bias applied to the semiconductor device 100 using the received Y-parameters, and extracts capacitance values from an imaginary part. Since sufficient description thereof has been given in the above with reference to [Mathematical Formula 1] to [Mathematical Formula 8], detailed description is not repeated here.

In operation S1120, the resistance extracting apparatus 120 receives parameter values measured in the turn-on state of the semiconductor device 100. The parameters may be Z-parameters of the semiconductor device 100.

Subsequently, in operation S1130, the resistance extracting apparatus 120 extracts resistance values which are dependent on the bias of the semiconductor device 100 using the received parameters, e.g. Z-parameters. The Z-parameters may be Z-parameters after de-embedding the received parameters. Since detailed description thereof has been given in the above with reference to [Mathematical Formula 9] to [Mathematical Formula 14], further description is not repeated here.

In summary, the resistance extracting apparatus 120 extracts the resistance values in the turn-off state using the Y-parameters as shown in FIG. 5. The extracted R_{elect}, Rₛₑ, R_{de}, C_{gse} and C_{gde} are de-embedded from the Z-parameters measured in the turn-on state. FIG. 4 shows an equivalent circuit before de-embedding. Z-parameters before de-embedding include all the parameters shown in FIG. 4. Therefore, in Z-parameters after de-embedding, i.e. in the turn-on state, since R_{elect}, Rₛₑ, R_{de}, C_{gse} and C_{gde} which are independent from the bias are removed, so C_{gd}, C_{gs}, R_{ch}, Rₛᵢ, and R_{di} which are dependent on the bias remain. Accordingly, the dependent values in the turn-on state are extracted.

If this process is performed by implementing an algorithm, each mathematical formula may correspond to each operation. Accordingly, the resistance extracting apparatus 120 may store the algorithms in a recording medium and execute the algorithms.

Subsequently, the resistance extracting apparatus 120 may verify reliability of the source and drain resistance extracting method as in FIG. 10 although reliability verification operation is not added to FIG. 11. Since detailed description thereof has been given in the above, further description is not repeated here.

Meanwhile, although all the components constituting the exemplary embodiments of the present invention are combined in one or operates in one system, the inventive concept of the present invention is not limited to the exemplary embodiments. That is, within the scope of the invention, all the components may be selectively combined and operated. In addition, each component may be implemented with independent hardware, or part or all of the components may be selectively combined and thus be implemented with a computer program having program modules which perform the combined functions in a single or a plurality of hardware. Codes and code segments constituting the computer program may be easily inferred by those skilled in the art. The computer program is stored in a computer-readable recording medium, and is read and executed by a computer, thereby implementing the exemplary embodiments of the present invention. The recording medium of the computer program may include magnetic recording media, optical recording media, and carrier wave media.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A resistance extracting apparatus comprising:
an interface unit which receives parameter values of a semiconductor device, which are measured in a turn-on state and a turn-off state of the semiconductor device;
a resistance value extracting unit which extracts resistance values which are independent from voltage applied to the semiconductor device using the parameter value measured in the turn-off state, and extracts resistance values which are dependent on the voltage using the parameter value measured in the turn-on state; and
a control unit which controls the resistance value extracting unit to extract the independent resistance values and the dependent resistance values using the received parameter values.

2. The resistance extracting apparatus as claimed in claim 1, wherein the resistance value extracting unit uses Y-parameter values of the semiconductor device to extract the independent resistance values, and uses Z-parameter values of the semiconductor device to extract the dependent resistance values.

3. The resistance extracting apparatus as claimed in claim 2, wherein the resistance value extracting unit extracts the independent resistance values in the turn-off state, de-embeds the extracted independent resistance values from the parameter value of the turn-on state, and extracts the dependent resistance values using the Z-parameter value after the de-embedding.

4. The resistance extracting apparatus as claimed in claim 1, wherein the resistance value extracting unit extracts each resistance value according to change in a frequency.

5. The resistance extracting apparatus as claimed in claim 1, wherein the semiconductor device includes heavily doped drain (HDD) areas and lightly doped drain (LDD) areas which are formed in a channel layer between a source electrode and a drain electrode, the HDD areas are formed adjacent to the source electrode and the drain electrode respectively, and the LDD areas are formed adjacent to the HDD areas respectively.

6. The resistance extracting apparatus as claimed in claim 5, wherein the HDD areas include the independent resistance values and the LDD areas include the dependent resistance values.

7. A resistance extracting method comprising:
receiving a parameter value measured in a turn-off state of a semiconductor device;
extracting resistance values which are independent from voltage applied to the semiconductor device using the parameter value measured in the turn-off state;
receiving a parameter value measured in a turn-on state of the semiconductor device; and
extracting resistance values which are dependent on the voltage applied to the semiconductor device using the parameter value measured in the turn-on state.

8. The resistance extracting method as claimed in claim 7, wherein in the extracting of the dependent resistance values, Z-parameter values are used, and in the extracting of the independent resistance values, Y-parameter values are used.

9. The resistance extracting method as claimed in claim 8, wherein in the extracting of the dependent resistance values, the dependent resistance values are extracted by de-embedding the independent resistance values which are measured and extracted in the turn-off state, from the Z-parameter values measured in the turn-on state.

10. The resistance extracting method as claimed in claim 7, wherein the semiconductor device includes heavily doped drain (HDD) areas and lightly doped drain (LDD) areas which are formed in a channel layer between a source electrode and a drain electrode, the HDD areas are formed adjacent to the source electrode and the drain electrode respectively, and the LDD areas are formed adjacent to the HDD areas respectively.

11. The resistance extracting method as claimed in claim 10, wherein in the extracting of the independent resistance values, resistance values of the HDD areas are extracted, and in the extracting of the dependent resistance values, resistance values of the LDD areas are extracted.

12. A computer-readable recording medium including a program to execute a resistance extracting method, wherein the resistance extracting method comprises:
receiving a parameter value measured in a turn-off state of a semiconductor device;
extracting resistance values which are independent from voltage applied to the semiconductor device using the parameter value measured in the turn-off state;
receiving a parameter value measured in a turn-on state of the semiconductor device; and
extracting resistance values which are dependent on the voltage applied to the semiconductor device using the parameter value measured in the turn-on state.
